(19) United States
(12) Patent Application Publication
(10) Pub. No.: US 2025/0391703 A1
(43) Pub. Date: Dec. 25, 2025

(54) MANUFACTURING METHOD OF SEMICONDUCTOR STRUCTURE

(71) Applicant: NANYA TECHNOLOGY CORPORATION, New Taipei City (TW)

(72) Inventors: Cheng Chieh SU, New Taipei City (TW); Chih-Ching LIN, New Taipei City (TW)

(21) Appl. No.: 18/748,085

(22) Filed: Jun. 20, 2024

(51) Int. Cl. H01L 21/762; H01L 21/311

(52) U.S. Cl. CPC H01L 21/76224; H01L 21/31144

(57) ABSTRACT

A manufacturing method of a semiconductor structure includes forming a plurality of trenches in a semiconductor layer and a liner layer of a semiconductor array, in which the liner layer is located on the semiconductor layer, forming an isolation layer in the trenches and on the liner layer, forming a nitrite layer on the isolation layer, patterning the nitrite layer, etching the isolation layer, the liner layer and the semiconductor layer by using the nitrite layer as a mask to form a plurality of through holes and refilling the isolation layer in the through holes and on the top surface of the liner layer.

### BACKGROUND

### FIELD OF INVENTION

The present disclosure relates to a manufacturing method of a semiconductor structure. More particularly, the present disclosure relates to a manufacturing method of a semiconductor structure having shallow trench isolation.

### DESCRIPTION OF RELATED ART

Among the manufacturing techniques of integrated circuits, shallow trench isolation is a technique used to create features that are capable of preventing current leakage between adjacent semiconductor devices.

Yet, it is difficult to simultaneously control the cut depth and width of a shallow trench isolation array structure fabricated by conventional manufacturing methods, and the island features of the shallow trench isolation array structure are fragile during conventional manufacturing processes, rendering the shallow trench isolation array structure prone to shorting.

### SUMMARY

According to one embodiment of the present disclosure, a manufacturing method of a semiconductor structure includes forming trenches in a semiconductor layer and a liner layer of a semiconductor array, in which the liner layer is located on the semiconductor layer; forming an isolation layer in the trenches and on the liner layer; forming a nitrite layer on the isolation layer, patterning the nitrite layer; and etching the isolation layer, the liner layer and the semiconductor layer by using the nitrite layer as a mask to form through holes and refilling the isolation layer in the through holes and on the top surface of the liner layer.

In some embodiments, patterning the nitrite layer includes forming a first photoresist layer on the nitrite layer, patterning the first photoresist layer, etching the nitrite layer by using the first photoresist layer as a mask to form a plurality of first openings and removing the first photoresist layer.

In some embodiments, etching the nitrite layer is performed such that the first openings are misaligned with the trenches in a vertical direction.

In some embodiments, patterning the nitrite layer includes forming an anti-reflective layer on the nitrite layer before forming the photoresist layer.

In some embodiments, patterning the nitrite layer further includes forming a second photoresist layer on the nitrite layer after the first photoresist layer is removed, patterning the second photoresist layer, etching the nitrite layer by using the second photoresist layer as a mask to form a plurality of second openings and removing the second photoresist layer.

In some embodiments, etching the nitrite layer is performed such that the second openings are misaligned with the trenches in a vertical direction.

In some embodiments, etching the nitrite layer is performed such that the second openings are misaligned with the first openings in the vertical direction.

In some embodiments, patterning the nitrite layer further includes forming a buffer layer on the nitrite layer and forming an anti-reflective layer on the buffer layer before forming the second photoresist layer.

In some embodiments, the manufacturing method of the semiconductor structure further includes removing the nitrite layer and the isolation layer above a top surface of the liner layer after etching the isolation layer, the liner layer and the semiconductor layer.

In some embodiments, the manufacturing method of the semiconductor structure further includes forming a carbon layer, an amorphous silicon layer, and a carbon oxide layer on the liner layer in sequence, in which the carbon oxide layer has a plurality of openings, and forming the trenches in the semiconductor layer and the liner layer of the semiconductor array comprises etching the semiconductor layer and the liner layer by using the carbon oxide layer as a mask and removing the carbon oxide layer, the amorphous silicon layer, and the carbon layer.

In some embodiments, a material of the semiconductor layer includes silicon, and a material of the liner layer includes tetraethoxysilane (TEOS) oxide.

According to another embodiment of the present disclosure, a manufacturing method of a semiconductor structure includes forming trenches in a semiconductor layer and a liner layer of a semiconductor array, wherein the liner layer is located on the semiconductor layer; forming an isolation layer in the trenches and on the liner layer; forming a nitrite layer on the isolation layer, forming a first photoresist layer on the nitrite layer; patterning the first photoresist layer; etching the nitrite layer by using the first photoresist layer as a mask to form the first openings; removing the first photoresist layer; and etching the isolation layer, the liner layer and the semiconductor layer by using the nitrite layer as a mask to form through holes.

In some embodiments, the first openings are misaligned with the trenches in a vertical direction.

In some embodiments, the manufacturing method of the semiconductor structure further includes forming an anti-reflective layer on the nitrite layer before forming the first photoresist layer.

In some embodiments, the manufacturing method of the semiconductor structure includes forming a second photoresist layer on the nitrite layer after the first photoresist layer is removed, patterning the second photoresist layer, etching the nitrite layer by using the second photoresist layer as a mask to form second openings and removing the second photoresist layer.

In some embodiments, the second openings are misaligned with the trenches in a vertical direction.

In some embodiments, the second openings are misaligned with the first openings in the vertical direction.

In some embodiments, the manufacturing method of the semiconductor structure further includes forming a buffer layer on the nitrite layer and forming an anti-reflective layer on the buffer layer before forming the second photoresist layer.

In some embodiments, the manufacturing method of the semiconductor structure further includes removing the nitrite layer and the isolation layer above a top surface of the liner layer after etching the isolation layer, the liner layer and the semiconductor layer.

In some embodiments, the manufacturing method of the semiconductor structure further includes forming a carbon layer, an amorphous silicon layer, and a carbon oxide layer on the liner layer in sequence, wherein the carbon oxide layer has a plurality of openings, and forming the trenches in the semiconductor layer and the liner layer of the semiconductor array comprises etching the semiconductor layer and the liner layer by using the carbon oxide layer as a mask and removing the carbon oxide layer, the amorphous silicon layer, and the carbon layer.

In the aforementioned embodiments, since the isolation layer is formed in the trenches before etching the liner layer and the semiconductor layer, the simultaneous control of cut depth and width of the shallow trench isolation features on the semiconductor array can be achieved, and the isolation layer is formed early to serve as a reinforcement structure to the semiconductor array during the manufacturing process. As a result, the semiconductor array can be prevented from structural collapse.

It is to be understood that both the foregoing general description and the following detailed description are by examples, and are intended to provide further explanation of the invention as claimed.

### BRIEF DESCRIPTION OF THE DRAWINGS

The present disclosure can be more fully understood by reading the following detailed description of the embodiment, with reference made to the accompanying drawings as follows:

FIG. 1 is a flow chart of a manufacturing method of a semiconductor structure according to one embodiment of the present disclosure.

FIGS. 2-6, 11 and 13 are cross-sectional views at intermediate stages of a manufacturing method of a semiconductor structure according to some embodiments of the present disclosure.

FIG. 7 is a top view of a semiconductor structure, in which FIG. 6 is a cross-sectional view taken along line 2-2 of FIG. 7.

FIGS. 8, 9, 12 and 14 are cross-sectional views at intermediate stages of the manufacturing method of the semiconductor structure after the step of FIG. 6.

FIG. 10 is a top view of a semiconductor structure, in which FIG. 9 is a cross-sectional view taken along line 8-8 of FIG. 10.

### DETAILED DESCRIPTION

Reference will now be made in detail to the present embodiments of the present disclosure, examples of which are illustrated in the accompanying drawings. Wherever possible, the same reference numbers are used in the drawings and the description to refer to the same or like parts.

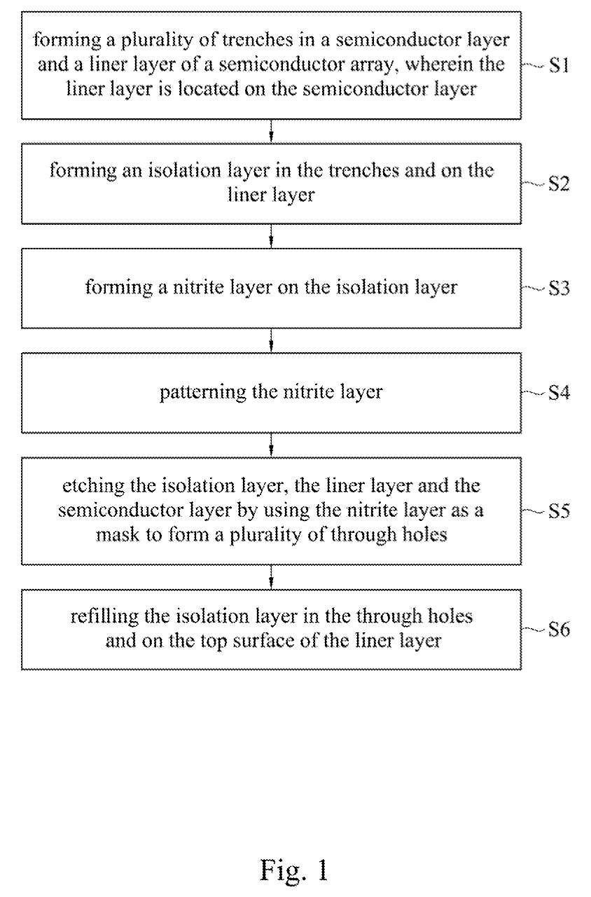

FIG. 1 is a flow chart of a manufacturing method of a semiconductor structure according to one embodiment of the present disclosure. Referring to FIG. 1, in step S1, a plurality of trenches are formed in a semiconductor layer and a liner layer of a semiconductor array, wherein the liner layer is located on the semiconductor layer. Thereafter, in step S2, an isolation layer is formed in the trenches and on the liner layer. Then, in step S3, a nitrite layer is formed on the isolation layer. Afterwards, in step S4, the nitrite layer is patterned. Subsequently, in step S5, the isolation layer, the liner layer and the semiconductor layer are etched by using the nitrite layer as a mask to form a plurality of through holes. Thereafter, in step S6, the isolation layer is refilled in the through holes and on the top surface of the liner layer.

Each of aforementioned steps S1 to S6 may include plural detailed steps. The manufacturing method of the semiconductor device may further include other steps between step S1 and step S6, and may include other steps before step S1 and after step S6. In the following description, step S1 to step S6 described above will be explained in detail.

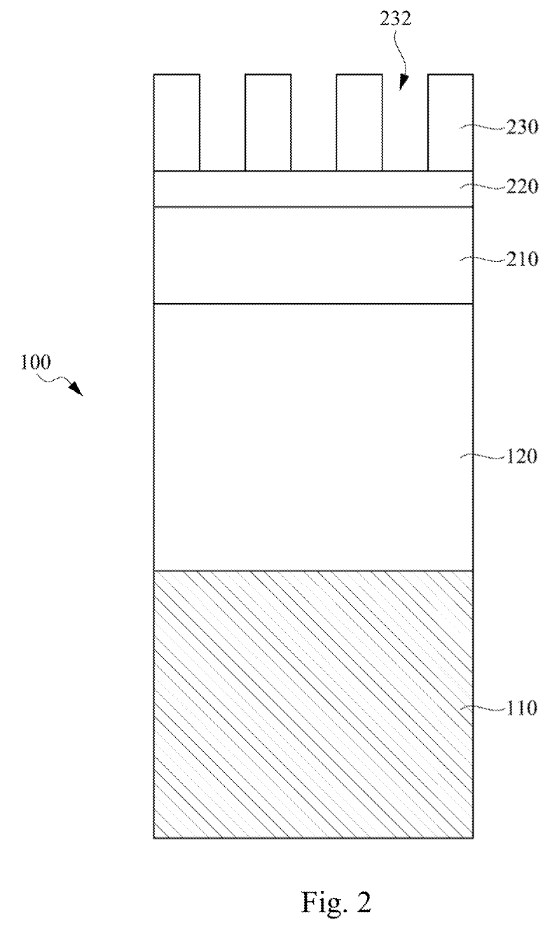

FIGS. 2-6, 11 and 13 are cross-sectional views at intermediate stages of a manufacturing method of a semiconductor structure according to some embodiments of the present disclosure. Referring to FIG. 2, a carbon layer 210, an amorphous silicon layer 220, and a carbon oxide layer 230 are formed on a liner layer 120 of a semiconductor array 100 in sequence, in which the carbon oxide layer 230 has a plurality of openings 232. The semiconductor array 100 includes a semiconductor layer 110 and a liner layer 120, in which the liner layer 120 is located on the semiconductor layer 110. In the present embodiment, the material of the semiconductor layer 110 may include silicon, and the material of the liner layer 120 may include tetraethoxysilane (TEOS) oxide.

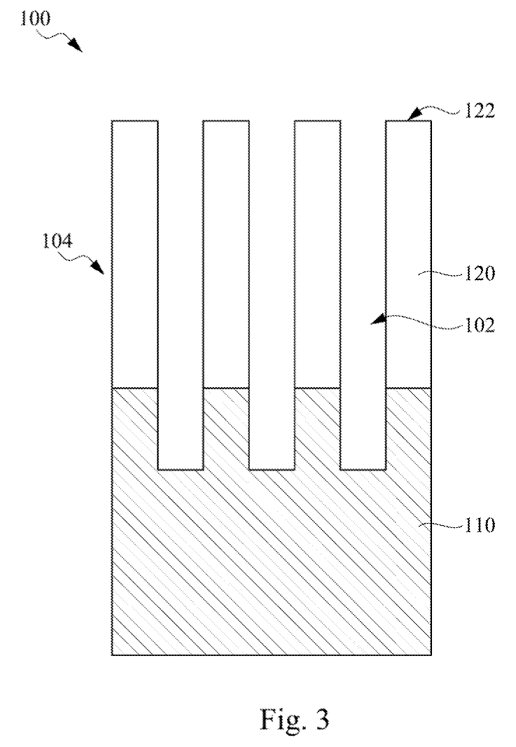

Thereafter, referring to FIGS. 2 and 3, trenches 102 are formed in the semiconductor layer 110 and the liner layer 120 of the semiconductor array 100. The semiconductor layer 110 and the liner layer 120 between trenches 102 define fin structures 104. In some embodiments, the semiconductor layer 110 and the liner layer 120 are etched by using the carbon oxide layer 230 as a mask to form the trenches 102 in the semiconductor layer 110 and the liner layer 120. After the semiconductor layer 110 and the liner layer 120 are etched, the carbon layer 210, the amorphous silicon layer 220 and the carbon oxide layer 230 are removed. In some embodiments, the carbon layer 210, the amorphous silicon layer 220 and the carbon oxide layer 230 are removed by dry-stripping process.

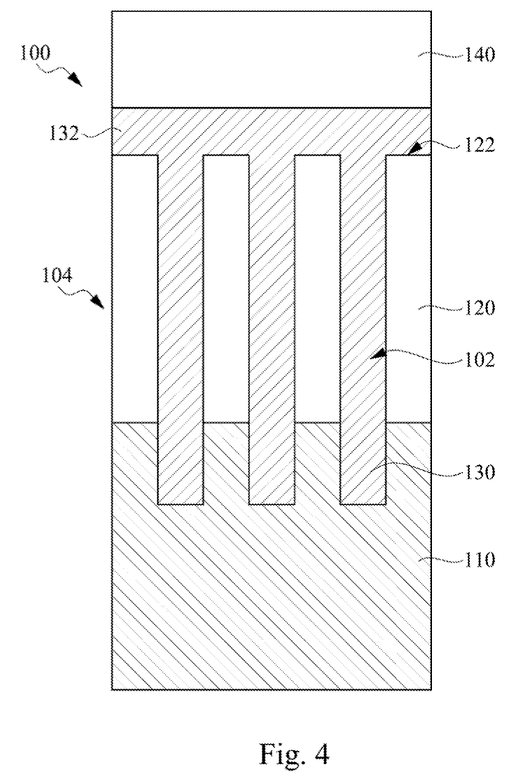

Thereafter, referring to FIG. 4, an isolation layer 130 is formed in the trenches 102 and on the liner layer 120. The isolation layer 130 has a portion 132 above the top surface 122 of the liner layer 120. In some embodiments, the isolation layer 130 can be formed by performing chemical vapor deposition (CVD). The formation of the isolation layer 130 in this step can reinforce the structure of semiconductor array 100 in the following manufacturing process. After forming the isolation layer 130, a nitrite layer 140 is formed on the isolation layer 130.

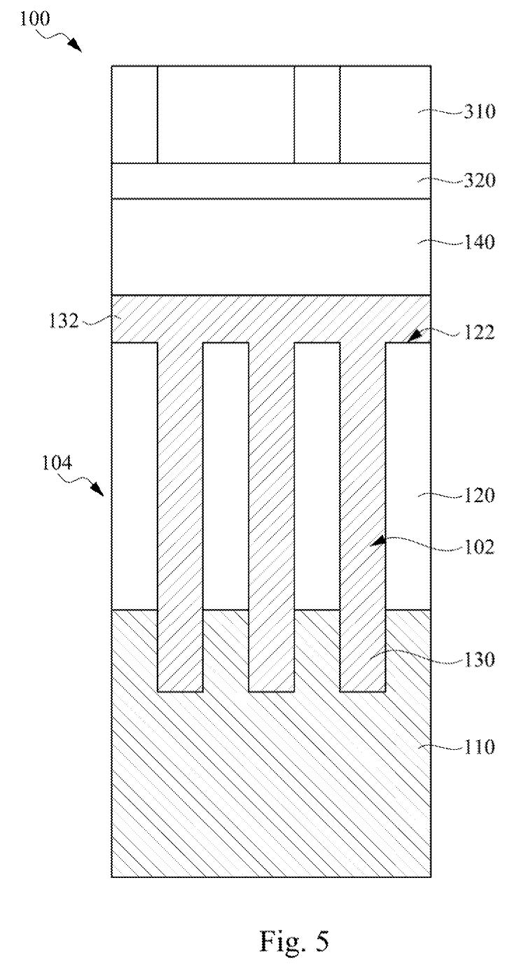

After forming the nitrite layer 140, referring to FIG. 5, a first photoresist layer 310 is formed on the nitrite layer 140. In the present embodiment, an anti-reflective layer 320 is formed on the nitrite layer 140 before the first photoresist layer 130 is formed. That is, the first photoresist layer 310 is formed on the anti-reflective layer 320, and the anti-reflective layer 320 is between the first photoresist layer 310 and the nitrite layer 140. Moreover, the first photoresist layer 310 is patterned to form openings such that the first photoresist layer 310 can serve as a mask for the following etch process to the nitrite layer 140. The anti-reflective layer 320 may be a bottom anti-reflective coating (BARC) that can improve the controlling of the pattern of the first photoresist layer 310.

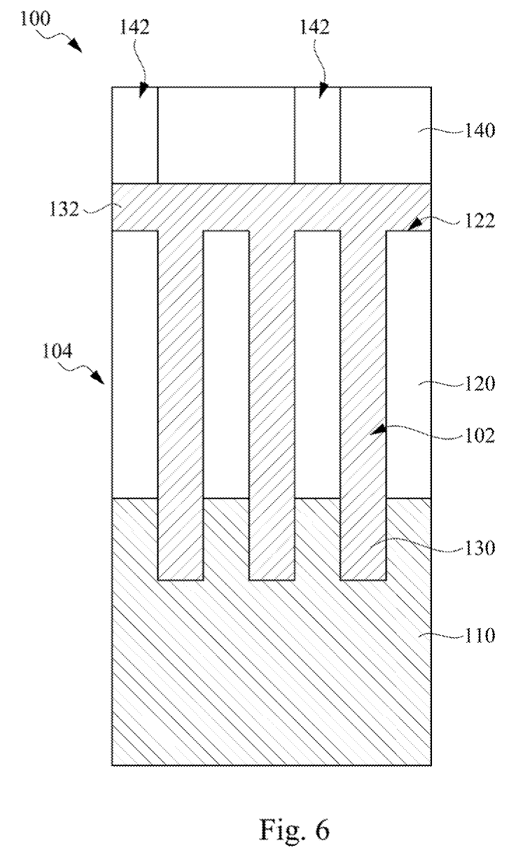

Thereafter, referring to FIGS. 5 and 6, the nitrite layer 140 is etched by using the first photoresist layer 310 as the mask to form first openings 142 in the nitrite layer 140. In some embodiments, the nitrite layer 140 is etched by dry-etching process. Thereafter, the first photoresist layer 310 is removed. In the present embodiment, the anti-reflective layer 320 is also removed. In addition, the first photoresist layer 310 can be removed by dry-stripping process.

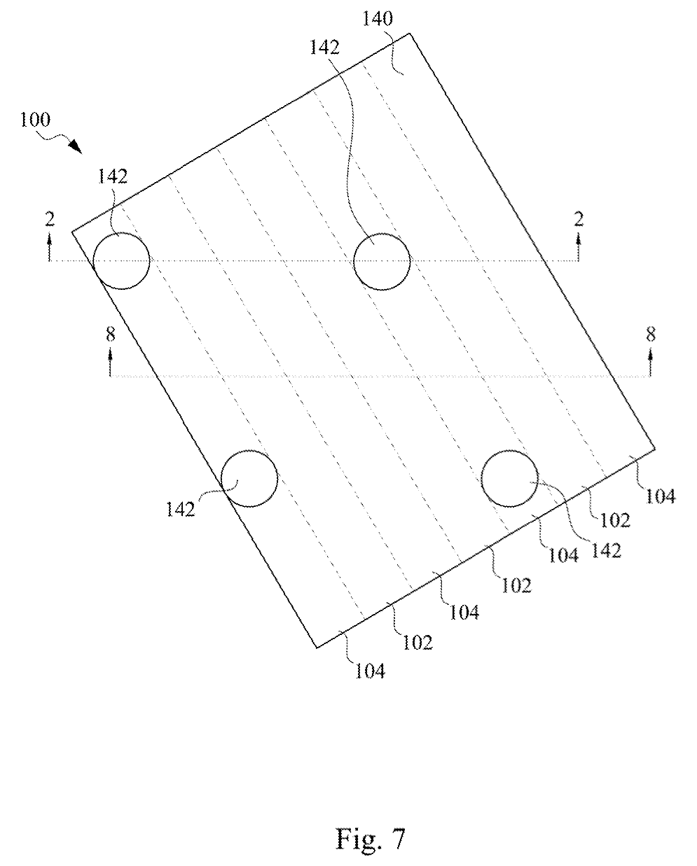

FIG. 7 is a top view of a semiconductor structure, in which FIG. 6 is a cross-sectional view taken along line 2-2 of FIG. 7. Referring to FIGS. 6 and 7, the nitrite layer 140 is etched such that the first openings 142 are misaligned with the trenches 102 in a vertical direction. Particularly, the first openings 142 are formed above the fin structures 104.

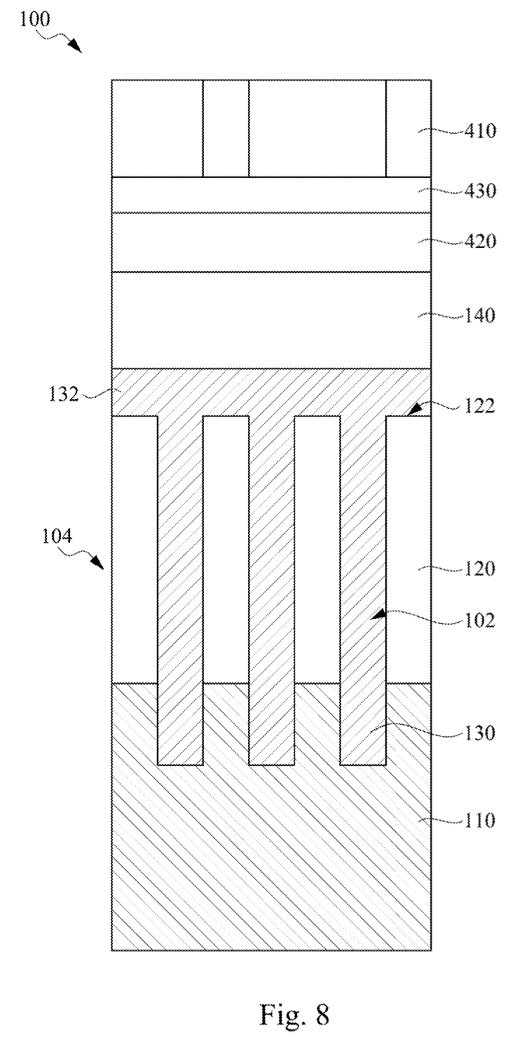

FIGS. 8, 9, 12 and 14 are cross-sectional views at intermediate stages of the manufacturing method of the semiconductor structure after the step of FIG. 6. FIG. 8 is a cross-sectional view of the semiconductor structure of FIG. 7 taken along line 8-8 after a buffer layer 420, an anti-reflective layer 430, and a second photoresist layer 410 are formed on the nitrite layer 140. Referring to FIG. 8, the second photoresist layer 410 is formed on the nitrite layer 140. In the present embodiment, the buffer layer 420 is formed on the nitrite layer 140, then the anti-reflective layer 430 is formed on the buffer layer 420, and the second photoresist layer 410 is formed on the anti-reflective layer 430. That is to say, the buffer layer 420, the anti-reflective layer 430 and the second photoresist layer 410 are formed in sequence such that the buffer layer 420 is between the nitrite layer 140 and the anti-reflective layer 430, and the anti-reflective layer 430 is between the buffer layer 420 and the second photoresist layer 410. Moreover, the second photoresist layer 410 is patterned to form openings such that the second photoresist layer 410 can serve as a mask for the following etch process to the nitrite layer 140. Nonetheless, the positions of the openings of the second photoresist layer 410 are different from the positions of the openings of the first photoresist layer 310. The buffer layer 420 provides a stronger bonding between the nitrite layer 140 and the photoresist layer 410. Similar to the anti-reflective layer 320 in FIG. 4, the anti-reflective layer 430 may be a bottom anti-reflective coating that can improve the controlling of the pattern of the second photoresist layer 410.

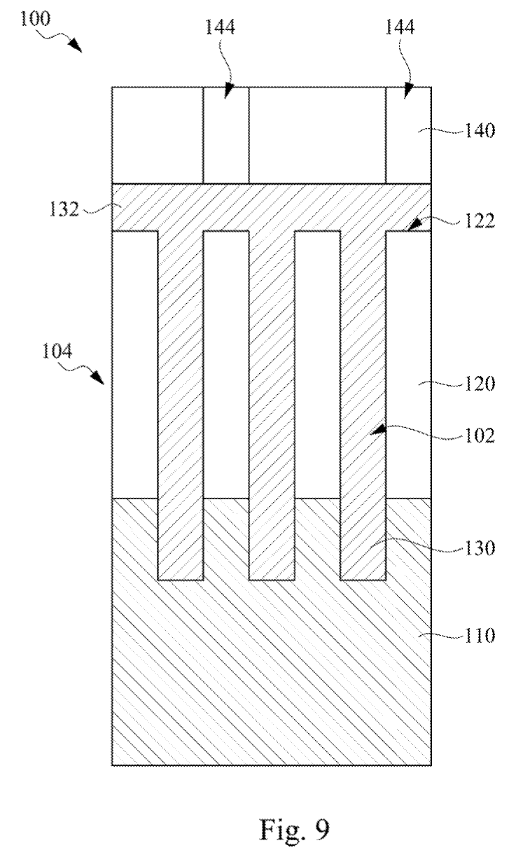

Thereafter, referring to FIGS. 8 and 9, the nitrite layer 140 is etched by using the second photoresist layer 410 as the mask to form second openings 144 in the nitrite layer 140. After the nitrite layer 140 is etched, the second photoresist layer 410 is removed. In the present embodiment, the buffer layer 420 and the anti-reflective layer 430 are also removed. In some embodiments, the second photoresist layer 410 is removed by dry-stripping process.

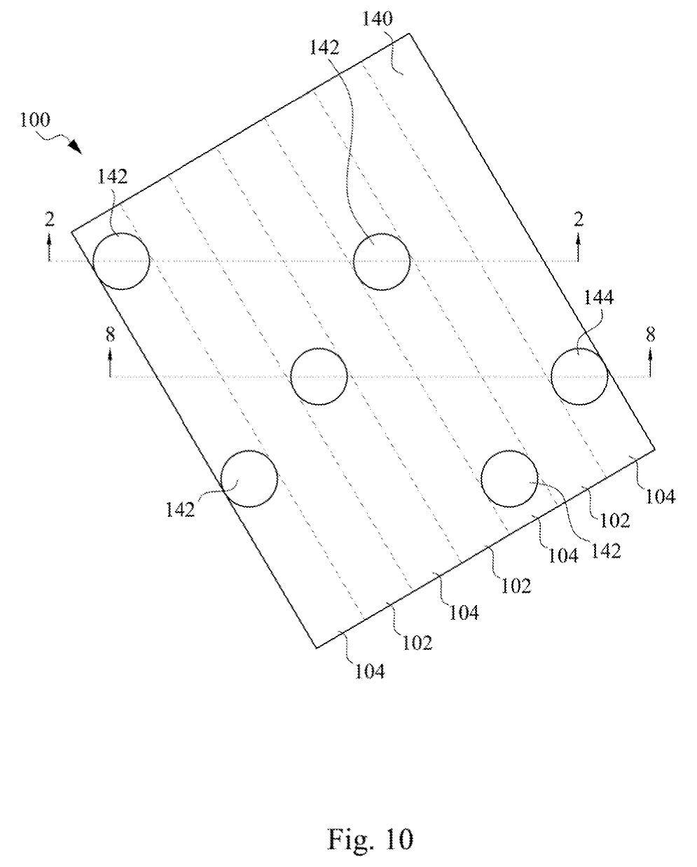

FIG. 10 is a top view of a semiconductor structure, in which FIG. 9 is a cross-sectional view taken along line 8-8 of FIG. 10. Referring to FIGS. 9 and 10, the nitrite layer 140 is etched such that the second openings 144 are misaligned with the trenches 102 in a vertical direction, and the second openings 144 are misaligned with the first openings 142 in the vertical direction and a horizontal direction. Particularly, the second openings 144 are formed above the fin structures 104 above which the first openings 142 are not formed.

Consequently, the nitrite layer 140 is patterned to have the first openings 142 and the second openings 144, such that the nitrite layer 140 can be used as a mask for the following etching process to the isolation layer 130, the liner layer 120 and the semiconductor layer 110 that are below the first openings 142 and the second openings 144 of the nitrite layer 140.

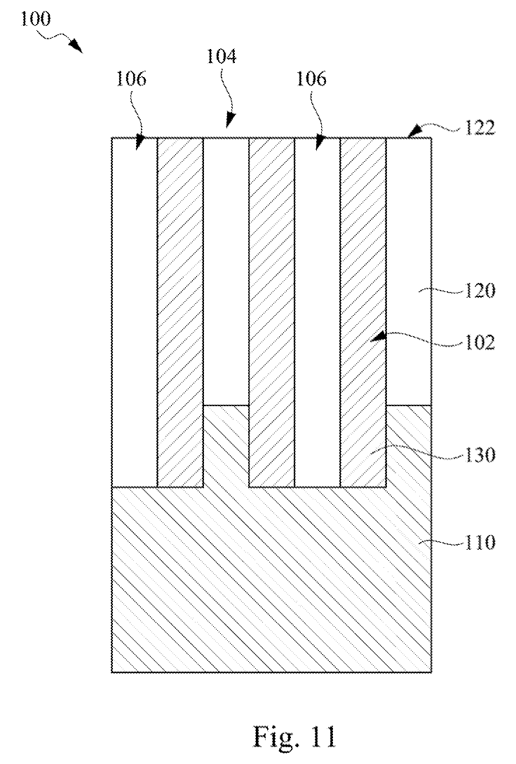

After the nitrite layer 140 is patterned, referring to FIGS. 6 and 11, the isolation layer 130, the liner layer 120 and the semiconductor layer 110 below the first openings 142 are etched by using the nitrite layer 140 as a mask to form through holes 106. The through holes 106 are located in the isolation layer 130 below the first openings 142. Particularly, the through holes 106 are formed by removing the fin structures 104 and the isolation layer 130 that are under the first openings 142 of the nitrite layer 140. In the present embodiment, the nitrite layer 140 and the portion 132 of the isolation layer 130 above the top surface 122 of the liner layer 120 are removed after the isolation layer 130, the liner layer 120 and the semiconductor layer 110 are etched to form the through holes 106.

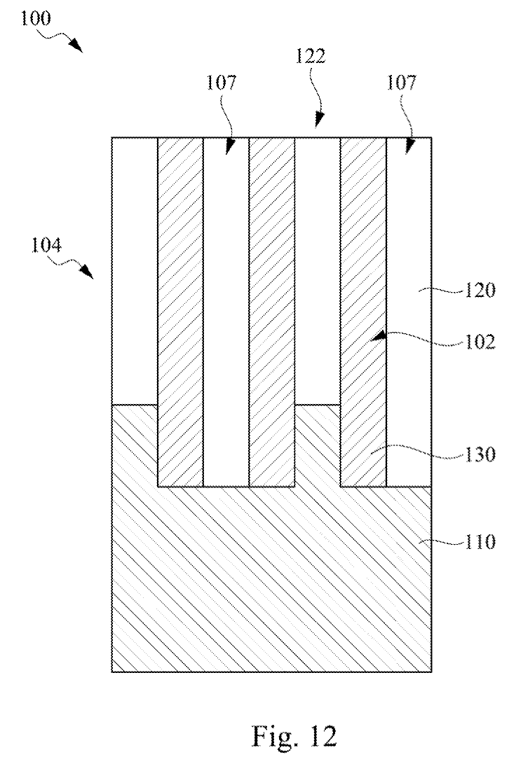

Also referring to FIGS. 9 and 12, during forming the through holes 106, the isolation layer 130, the liner layer 120 and the semiconductor layer 110 below second openings 144 are etched by using the nitrite layer 140 as a mask to simultaneously form through holes 107. In other words, the through holes 107 are located in the isolation layer 130 below the second openings 144. Particularly, the through holes 107 are also formed by removing the fin structures 104 and the isolation layer 130 that are under the second openings 144. The fin structures 104 are thereby surrounded by the trenches 102 and through holes 106 and 107, in which the through holes 106 and 107 divide the fin structures 104 into island sections.

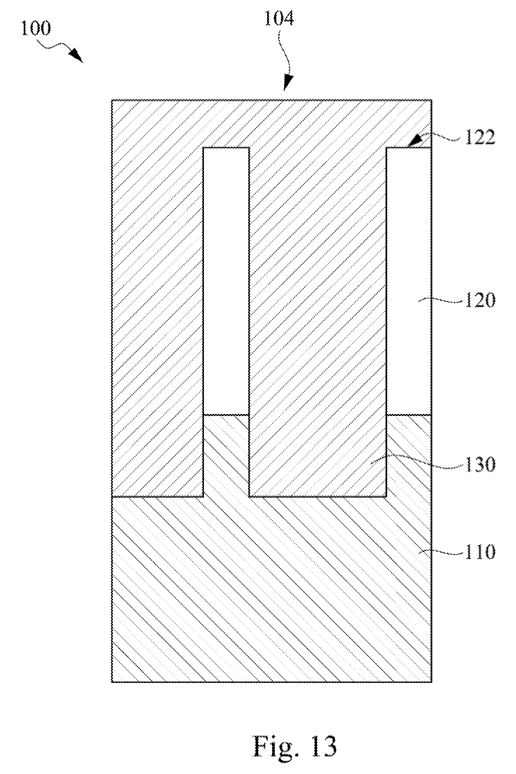

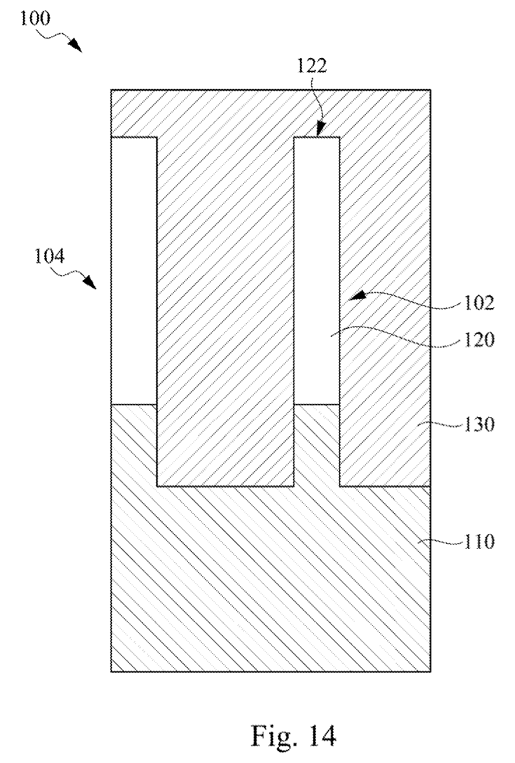

Thereafter, referring to FIGS. 13 and 14, the isolation layer 130 is refilled on the top surface 122 of the liner layer 120 and in the trenches 102 and the through holes 106 and 107 shown in FIGS. 11 and 12.

The fin structures 106 are thereby isolated by the isolation layer 110. The isolation layer 110 is referred to as shallow trench isolation (STI). After the formation of the refilled isolation layer 110, the semiconductor structure having the shallow trench isolation is an array structure with island-like features.

To sum up, since the isolation layer is formed in the trenches before etching the liner layer and the semiconductor layer, the simultaneous control of cut depth and width of the shallow trench isolation features on the semiconductor array can be achieved, and the isolation layer is formed early to serve as a reinforcement structure to the semiconductor array during the manufacturing process. As a result, the semiconductor array can be prevented from structural collapse.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims.

What is claimed is:

1. A manufacturing method of a semiconductor structure, comprising:
forming a plurality of trenches in a semiconductor layer and a liner layer of a semiconductor array, wherein the liner layer is located on the semiconductor layer;
forming an isolation layer in the trenches and on the liner layer;
forming a nitrite layer on the isolation layer;
patterning the nitrite layer;
etching the isolation layer, the liner layer and the semiconductor layer by using the nitrite layer as a mask to form a plurality of through holes; and
refilling the isolation layer in the through holes and on the top surface of the liner layer.

2. The manufacturing method of claim 1, wherein patterning the nitrite layer comprises:
forming a first photoresist layer on the nitrite layer;
patterning the first photoresist layer;
etching the nitrite layer by using the first photoresist layer as a mask to form a plurality of first openings; and
removing the first photoresist layer.

3. The manufacturing method of claim 2, wherein etching the nitrite layer is performed such that the first openings are misaligned with the trenches in a vertical direction.

4. The manufacturing method of claim 2, wherein patterning the nitrite layer further comprises:
forming an anti-reflective layer on the nitrite layer before forming the photoresist layer.

5. The manufacturing method of claim 2, wherein patterning the nitrite layer further comprises:
forming a second photoresist layer on the nitrite layer after the first photoresist layer is removed;
patterning the second photoresist layer;
etching the nitrite layer by using the second photoresist layer as a mask to form a plurality of second openings; and
removing the second photoresist layer.

6. The manufacturing method of claim 5, wherein etching the nitrite layer is performed such that the second openings are misaligned with the trenches in a vertical direction.

7. The manufacturing method of claim 6, wherein etching the nitrite layer is performed such that the second openings are misaligned with the first openings in the vertical direction.

8. The manufacturing method of claim 5, wherein patterning the nitrite layer further comprises:
forming a buffer layer on the nitrite layer; and
forming an anti-reflective layer on the buffer layer before forming the second photoresist layer.

9. The manufacturing method of claim 1, further comprising:
removing the nitrite layer and the isolation layer above a top surface of the liner layer after etching the isolation layer, the liner layer and the semiconductor layer.

10. The manufacturing method of claim 1, further comprising:
forming a carbon layer, an amorphous silicon layer, and a carbon oxide layer on the liner layer in sequence, wherein the carbon oxide layer has a plurality of openings, and forming the trenches in the semiconductor layer and the liner layer of the semiconductor array comprises etching the semiconductor layer and the liner layer by using the carbon oxide layer as a mask; and
removing the carbon oxide layer, the amorphous silicon layer, and the carbon layer.

11. The manufacturing method of claim 1, wherein a material of the semiconductor layer comprises silicon, and a material of the liner layer comprises tetraethoxysilane (TEOS) oxide.

12. A manufacturing method of a semiconductor structure, comprising:
forming a plurality of trenches in a semiconductor layer and a liner layer of a semiconductor array, wherein the liner layer is located on the semiconductor layer;
forming an isolation layer in the trenches and on the liner layer;
forming a nitrite layer on the isolation layer;
forming a first photoresist layer on the nitrite layer;
patterning the first photoresist layer;
etching the nitrite layer by using the first photoresist layer as a mask to form the first openings;
removing the first photoresist layer; and
etching the isolation layer, the liner layer and the semiconductor layer by using the nitrite layer as a mask to form a plurality of through holes.

13. The manufacturing method of claim 12, wherein the first openings are misaligned with the trenches in a vertical direction.

14. The manufacturing method of claim 12, further comprises:
forming an anti-reflective layer on the nitrite layer before forming the first photoresist layer.

15. The manufacturing method of claim 12, further comprising:
forming a second photoresist layer on the nitrite layer after the first photoresist layer is removed;
patterning the second photoresist layer;
etching the nitrite layer by using the second photoresist layer as a mask to form a plurality of second openings; and
removing the second photoresist layer.

16. The manufacturing method of claim 15, wherein the second openings are misaligned with the trenches in a vertical direction.

17. The manufacturing method of claim 16, wherein the second openings are misaligned with the first openings in the vertical direction.

18. The manufacturing method of claim 15, further comprising:
forming a buffer layer on the nitrite layer; and
forming an anti-reflective layer on the buffer layer before forming the second photoresist layer.

19. The manufacturing method of claim 12, further comprising
removing the nitrite layer and the isolation layer above a top surface of the liner layer after etching the isolation layer, the liner layer and the semiconductor layer.

20. The manufacturing method of claim 12, further comprising:
forming a carbon layer, an amorphous silicon layer, and a carbon oxide layer on the liner layer in sequence, wherein the carbon oxide layer has a plurality of openings, and forming the trenches in the semiconductor layer and the liner layer of the semiconductor array comprises etching the semiconductor layer and the liner layer by using the carbon oxide layer as a mask; and
removing the carbon oxide layer, the amorphous silicon layer, and the carbon layer.
